(19) United States
(12) Patent Application Publication
(10) Pub. No.: US 2024/0141496 A1
(43) Pub. Date: May 2, 2024

(54) DEPOSITION APPARATUS

(71) Applicant: Samsung Display Co., Ltd., Yongin-si (KR)

(72) Inventors: GYEONGHEE HAN, Yongin-si (KR); BYUNGHUN SUNG, Yongin-si (KR); SANGKEUN LEE, Yongin-si (KR)

(73) Assignee: Samsung Display Co., Ltd., Yongin-si (KR)

(21) Appl. No.: 18/459,587

(22) Filed: Sep. 1, 2023

(30) Foreign Application Priority Data
Oct. 28, 2022 (KR) 10-2022-0140938

(51) Int. Cl. C23C 16/458

(52) U.S. Cl. CPC C23C 16/4586; C23C 16/4584

(57) ABSTRACT

A deposition apparatus including a support unit that supports a second surface of a substrate having a first surface and the second surface opposed to the first surface, and a chuck having a first pattern portion and a second pattern portion that are adjacent to each other, and receive different voltages, respectively. The substrate has a first part overlapping the first pattern portion of the chuck and a second part overlapping the second pattern portion of the chuck, and the support unit has a first support unit and a second support unit that support different portions of the second part.

### CROSS-REFERENCE TO RELATED APPLICATION(S)

This application claims priority to and benefits of Korean Patent Application No. 10-2022-0140938 under 35 U.S.C. § 119, filed on Oct. 28, 2022, the entire contents of which are incorporated herein by reference.

### BACKGROUND

### 1. Technical Field

Embodiments relate to a deposition apparatus with a chuck and a support unit.

### 2. Description of the Related Art

Electronic apparatuses such as smartphones, tablet computers, laptop computers, and smart televisions have been developed. Such electronic apparatuses include display devices in order to provide information. A display device is fabricated by repeating, multiple times, the following processes including a thin film deposition process for forming, on a substrate surface, a thin film made of a certain material, a photolithography process for exposing a selected portion of the thin film, and a dry or wet etching process for removing the exposed portion of the thin film to form suitable patterns. Among these processes, a thin film deposition process, a dry etching process, and the like are generally performed in sealed process chambers, and an electrostatic chuck, a temperature control module, and the like may be provided in each of the process chambers to fix a substrate.

### SUMMARY

Embodiments provide a deposition apparatus capable of improving process reliability and reducing the process costs and the process time by preventing sagging of a substrate to avoid the occurrence of defects such as shadows in a deposition process.

Embodiments also provide a deposition apparatus capable of preventing sagging of a substrate using a chuck and a support unit.

Embodiments also provide a deposition apparatus capable of effectively preventing sagging of a large-sized substrate by determining the positions of support units by reflecting a degree of deflection of the substrate caused by the increase in size of the substrate.

Embodiments also provide a deposition apparatus capable of effectively preventing sagging of a substrate by reflecting a degree of deflection in each portion of the substrate, and by varying a pattern portion for each portion of a chuck.

However, embodiments of the disclosure are not limited to those set forth herein. The above and other embodiments will become more apparent to one of ordinary skill in the art to which the disclosure pertains by referencing the detailed description of the disclosure given below.

In an embodiment, a deposition apparatus may include a support unit that supports a second surface of a substrate having a first surface and the second surface opposed to the first surface, and a chuck facing the first surface of the substrate, and having a first pattern portion and a second pattern portion that are adjacent to each other, and receive different voltages, respectively, wherein the substrate may include a first part overlapping the first pattern portion of the chuck and a second part overlapping the second pattern portion of the chuck, and the support unit may include a first support unit and a second support unit that support different portions of the second part of the substrate.

In an embodiment, each of the first pattern portion and the second pattern portion of the chuck may include a plurality of pattern electrodes, and first pattern portion and the second pattern portion of the chuck may be different numbers of the pattern electrodes per unit area from each other.

In an embodiment, the deposition apparatus may further include a deposition chamber including an inner space accommodating the support unit, the substrate, and the chuck, and a stage accommodated in the inner space of the deposition chamber, and spaced apart from the chuck with the substrate disposed between the stage and the chuck, wherein the first support unit may include a first shaft extending from the deposition chamber to the inner space of the deposition chamber, a frame connected to the first shaft, and surrounding the substrate, and a first support member extending from the frame toward the substrate, and the second support unit may include a pair of first support parts extending from the stage to the substrate, and a second support part extending in a direction intersecting an extending direction of the pair of first support parts to connect the pair of first support parts to each other.

In an embodiment, the stage may include a rail extending in a direction, and the second support unit may further include a moveable member that has a side coupled to the pair of first support parts and another side coupled to the rail, and is moveable in the direction.

In an embodiment, the second support part may include a protruding portion protruding toward the second surface of the substrate.

In an embodiment, the second support unit may be provided in plurality.

In an embodiment, the deposition apparatus may further include a deposition chamber including an inner space accommodating the support unit, the substrate, and the chuck, wherein the first support unit may include a first shaft extending from the deposition chamber to the inner space of the deposition chamber, a frame connected to the first shaft, and surrounding the substrate, and a first support member extending from the frame toward the substrate, and the second support unit may include a second shaft extending to the inner space of the deposition chamber, and a second support member that bends and extends from the second shaft, and rotates about the second shaft to move.

In an embodiment, the second support unit may further include a driving member that moves the second support member by rotating or lifting/lowering the second support member, and a coupling member that couples the driving member to the second shaft.

In an embodiment, the second support member may include a plurality of sub-members extending in different directions, respectively.

In an embodiment, each of the plurality of sub-members may include a protruding portion protruding toward the second surface of the substrate.

In an embodiment, a deposition apparatus may include a support unit that supports a second surface of a substrate having a first surface and the second surface opposed to the first surface, and a chuck facing the first surface, and having a first pattern portion and a second pattern portion that are adjacent to each other, and receive different voltages, wherein the substrate may include a first part overlapping the first pattern portion of the chuck, and spaced apart from the chuck by a first distance, and a second part overlapping the second pattern portion of the chuck, and spaced apart from the chuck by a second distance different from the first distance, and the support unit may include a first support unit and a second support unit that support different portions of the second part.

In an embodiment, each of the first pattern portion and the second pattern portion may include a plurality of pattern electrodes, and the first pattern portion and the second pattern portion may have different numbers of the pattern electrodes per unit area from each other.

In an embodiment, the deposition apparatus may further include a deposition chamber including an inner space accommodating the support unit, the substrate, and the chuck, and a stage accommodated in the inner space of the deposition chamber, and spaced apart from the chuck with the substrate disposed between the stage and the chuck, wherein the first support unit may include a first shaft extending from the deposition chamber to the inner space of the deposition chamber, a frame connected to the first shaft, and surrounding the substrate, and a first support member extending from the frame toward the substrate, the stage may include a rail extending in a direction, and the second support unit may further include a pair of first support parts extending from the stage to the substrate, a second support part extending in a direction intersecting an extending direction of the pair of first support parts to connect the pair of first support parts to each other, and a moveable member that has a side coupled to the first support and another side coupled to the rail, and is moveable in the direction.

In an embodiment, the deposition apparatus may further include a deposition chamber including an inner space accommodating the support unit, the substrate, and the chuck, wherein the first support unit may include a first shaft extending from the deposition chamber to the inner space of the deposition chamber, a frame connected to the first shaft, and surrounding the substrate, and a first support member extending from the frame toward the substrate, and the second support unit may include a second shaft extending to the inner space of the deposition chamber, a second support member that bends and extends from the second shaft, and rotates about the second shaft to move, and a driving member coupled to the second shaft, and that moves the second support member by rotating or lifting/lowering the second support member.

In an embodiment, a deposition apparatus may include a support unit that supports a second surface of a substrate having a first surface and the second surface opposed to the first surface, and a chuck facing the first surface of the substrate, and that fixes the substrate to the support unit, wherein the substrate may include a first part spaced apart from the chuck by a first distance, and a second part adjacent to the first part, and spaced apart from the chuck by a second distance different from the first distance, and the support unit may include a first support unit and a second support unit that support different portions of the second part.

In an embodiment, the chuck may include a first pattern portion overlapping the first part of the substrate, and a second pattern portion overlapping the second part of the substrate, wherein the first pattern portion and the second pattern portion may be configured to receive different voltages, respectively.

In an embodiment, each of the first pattern portion and the second pattern portion of the chuck may include a plurality of pattern electrodes, and the first pattern portion and the second pattern portion may be different electrode areas from each other.

In an embodiment, each of the first pattern portion and the second pattern portion of the chuck may include a plurality of pattern electrodes, and the first pattern portion and the second pattern portion may be different numbers of the pattern electrodes per unit area from each other.

In an embodiment, the deposition apparatus may further include a deposition chamber including an inner space accommodating the support unit, the substrate, and the chuck, and a stage accommodated in the inner space of the deposition chamber, and spaced apart from the chuck with the substrate disposed between the stage and the chuck, wherein the first support unit may include a first shaft extending from the deposition chamber to the inner space of the deposition chamber, a frame connected to the first shaft, and surrounding the substrate, and a first support member extending from the frame toward the substrate, the stage may include a rail extending in a direction, and the second support unit may further include a pair of first support parts extending from the stage to the substrate, a second support part extending in a direction intersecting an extending direction of the pair of first support parts to connect the pair of first support parts to each other, and a moveable member that has a side coupled to the pair of first support parts and another side coupled to the rail, and is moveable in the direction.

In an embodiment, the deposition apparatus may further include a deposition chamber including an inner space accommodating the support unit, the substrate, and the chuck, wherein the first support unit may include a first shaft extending from the deposition chamber to the inner space of the deposition chamber, a frame connected to the first shaft, and surrounding the substrate, and a first support member extending from the frame to the substrate, and the second support unit may include a second shaft extending to the inner space of the deposition chamber, a second support member that bends and extends from the second shaft, and rotates about the second shaft to move, and a driving member coupled to the second shaft, and that moves the second support member by rotating or lifting/lowering the second support member.

### BRIEF DESCRIPTION OF THE DRAWINGS

The accompanying drawings are included to provide a further understanding of the invention, and are incorporated in and constitute a part of this specification. The drawings illustrate embodiments and, together with the description, serve to explain principles of the invention. In the drawings:

FIG. 1 is a schematic diagram of a deposition apparatus according to an embodiment;

FIGS. 2A and 2B are schematic diagrams illustrating a part of a deposition apparatus according to an embodiment;

FIG. 3A is a schematic diagram illustrating a part of a deposition apparatus according to an embodiment;

FIG. 3B is an enlarged schematic view of a part of FIG. 3A;

FIG. 4A is a diagram illustrating a part of a deposition apparatus according to an embodiment;

FIG. 4B is an enlarged schematic view illustrating a part of FIG. 4A;

FIG. 5 is a schematic diagram illustrating experimental results of a deposition apparatus according to an embodiment and a comparison target;

FIGS. 6A through 6C are schematic diagrams illustrating a part of a deposition apparatus according to an embodiment;

FIGS. 7A and 7B are schematic diagrams illustrating a part of a deposition apparatus according to an embodiment;

FIG. 8 is a schematic diagram illustrating experimental results of a deposition apparatus according to an embodiment and a comparison target;

FIG. 9 is a schematic diagram of a deposition apparatus according to an embodiment;

FIGS. 10A and 10B are schematic diagrams illustrating a part of a deposition apparatus according to an embodiment;

FIGS. 11A through 11C are schematic diagrams illustrating a part of a deposition apparatus according to an embodiment;

FIGS. 12A through 12E are schematic diagrams illustrating some operations of a deposition method by using a deposition apparatus according to an embodiment; and

FIGS. 13A through 13D are schematic diagrams illustrating some operations of a deposition method by using a deposition apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

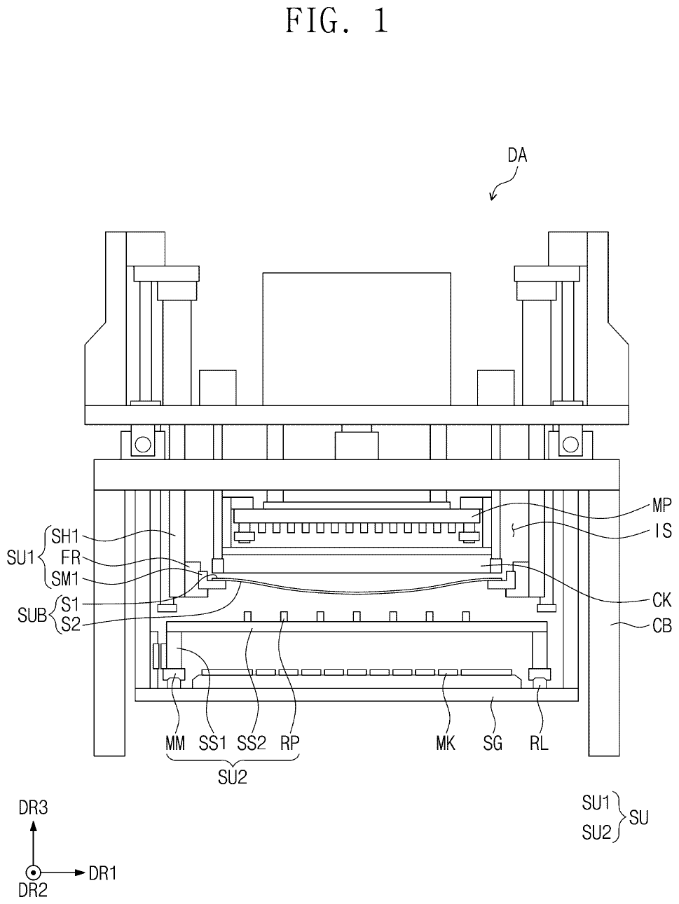

FIG. 1 is a schematic diagram of a deposition apparatus according to an embodiment. FIG. 1 is a schematic diagram illustrating a schematic front view of a deposition apparatus DA according to an embodiment.

Referring to FIG. 1, the deposition apparatus DA according to an embodiment may include a support unit SU, a chuck CK, and a deposition chamber CB.

The deposition chamber CB may provide a space therein. An inner space IS defined inside the deposition chamber CB may accommodate the support unit SU, a substrate SUB, and the chuck CK. The deposition chamber CB may form a sealed space therein, and set the deposition condition to a vacuum state. The deposition chamber CB may have at least one gate, and may be opened and closed by the gate. A mask MK and the substrate SUB may enter and exit the deposition chamber CB through the gate provided on the deposition chamber CB.

The deposition chamber CB may include a floor, a ceiling, and a plurality of sidewalls. The floor, the ceiling, and the plurality of sidewalls may form the deposition chamber CB in a box shape. The floor of the deposition chamber CB may be parallel to the plane defined by a first direction DR1 and a second direction DR2, and the normal direction of the floor of the deposition chamber CB may be parallel to a third direction DR3. The third direction DR3 may be parallel to and opposite to the direction of gravity. In the description, the term “on a plane” and “in a plan view” is set based on a plane parallel to the plane defined by the first direction DR1 and the second direction DR2.

The mask MK may be positioned inside the deposition chamber CB. The mask MK may include an opening which defines a deposition region.

A magnetic plate MP may bring the substrate SUB into close contact with the mask MK by magnetic forces.

A stage SG may be positioned inside the deposition chamber CB. The mask MK may be disposed on the stage SG, and a portion of the support unit SU may be disposed on the stage SG. The stage SG may include a rail RL. A second support unit SU2 to be described below may be moveable along the rail RL in the second direction DR2.

A deposition member may be accommodated in the deposition chamber CB. The deposition member may include a space, in which a deposition material is accommodated, and at least one nozzle. The deposition material may include a sublimable or a vaporizable inorganic material, a metal material, or an organic material. The deposition material may be sprayed toward the substrate SUB through the nozzle. The deposition material may pass through the mask MK, and may be deposited on the substrate SUB in a certain pattern.

The substrate SUB may be an object to be processed on which the deposition material is deposited. The substrate SUB may be supported by the support unit SU or the chuck CK. The substrate SUB may be accommodated in the inner space IS of the deposition chamber CB. The substrate SUB may include an upper surface and a lower surface opposed to the upper surface. As illustrated in the drawing, the chuck CK may be disposed at a location adjacent to the upper surface of the substrate SUB, and the support unit SU may be disposed at a location adjacent to the lower surface of the substrate SUB. An embodiment may prevent sagging (or bending) of such a substrate SUB facing downwards.

The substrate SUB may include a first surface S1 and a second surface S2 opposed to the first surface S1. The first surface S1 of the substrate SUB may be defined as the upper surface, and the second surface S2 may be defined as the lower surface.

The support unit SU may be disposed inside the deposition chamber CB. The support unit SU may support the substrate SUB. The support unit SU may support the substrate SUB at a location adjacent to the chuck CK. For example, by moving the position of the support unit SU, the substrate SUB may be supported on the mask MK. The support unit SU may include, for example, a jig or a robot arm.

The support unit SU may include a first support unit SU1 and a second support unit SU2. The first support unit SU1 and the second support unit SU2 may support different portions of the substrate SUB. According to an embodiment, the first support unit SU1 and the second support unit SU2 may support the lower portion of the substrate SUB. For example, the first support unit SU1 may support the lower corner portions of the substrate SUB, and the second support unit SU2 may support the lower central portion of the substrate SUB.

The support unit SU may be in contact with the substrate SUB to support the substrate SUB, but an embodiment is not limited thereto, and the substrate SUB may be supported through a clamp method, etc. The method by which the support unit SU supports the substrate SUB is not limited to any one method, and various methods may be employed as long as damage to the substrate SUB is prevented.

The first support unit SU1 may support a portion of the substrate SUB. The second support unit SU2 may support another portion of the substrate SUB. However, the first support unit SU1 and the second support unit SU2 may not always support different portions of the substrate SUB, and may also support the overlapped portion of the substrate SUB.

The first support unit SU1 may include a first shaft SH1, a frame FR, and a first support member SM1. The first support unit SU1 may be provided in plurality.

The first shaft SH1 may extend from the deposition chamber CB to the inner space IS. The frame FR may be connected to the first shaft SH1, and surround the substrate SUB. For example, the frame FR may surround the entire circumference of the substrate SUB, but embodiments are not limited thereto, and the frame FR may surround a portion of the circumference of the substrate SUB. The first support member SM1 may extend from the frame FR toward the substrate SUB. A portion of the first support member SM1 may be in contact with the lower portion of the substrate SUB, thereby making it possible for the first support unit SU1 to support the substrate SUB. The first support member SM1 may not be the only one component in contact with the lower portion of the substrate SUB, and a portion of the frame FR may also be in contact with the lower portion of the substrate SUB, thereby making it possible for the first support unit SU1 to support the substrate SUB.

The first shaft SH1 may move up and down in the inner space IS. Accordingly, the frame FR and the first support member SM1 may move up and down in the inner space IS, and support the substrate SUB at various positions.

The second support unit SU2 may include a first support part SS1, a second support part SS2, and a moveable member MM. The second support unit SU2 may be provided in plurality.

The first support part SS1 may extend from the stage SG to the substrate SUB. For example, the first support part SS1 may extend in the third direction DR3. A pair of first support parts SS1 may be positioned respectively on sides (e.g., opposite sides) of the substrate SUB with the substrate SUB therebetween. The second support part SS2 may extend in a direction intersecting the extending direction of the first support parts SS1, and support the pair of first support parts SS1. For example, the second support part SS2 may extend in the first direction DR1 to be connected to the pair of first support parts SS1. The moveable member MM may have a side connected to the first support part SS1, and another side connected to the rail RL. The moveable member MM may be moveable along an extending direction of the rail RL on the stage SG, and moveable along the second direction DR2 as illustrated in the drawing. Accordingly, the first support part SS1 and the second support part SS2 may support the substrate SUB at various positions while moving along the rail RL. For example, the positions of the first support part SS1 and the second support part SS2 may be fixed at optimal positions for preventing sagging of the substrate SUB. The optimal position may not be a fixed position, and may vary according to a design of the deposition apparatus DA, and a size of the substrate SUB, etc.

The second support unit SU2 may be provided in plurality. For example two or more second support units SU2 may be provided in order to effectively support the substrate SUB and thus effectively prevent the substrate SUB from sagging.

The height of the first support part SS1 may be fixed or constant. However, the first support part SS1 may also be provided such that the height thereof is changeable, similarly to the first shaft SH1 as described above. Accordingly, the second support part SS2 may move up and down in the inner space IS, and support the substrate SUB at various positions.

The chuck CK may be disposed inside the deposition chamber CB. The chuck CK may be positioned adjacent to the substrate SUB, and support the substrate SUB. According to an embodiment, the chuck CK may be positioned above the substrate SUB, but embodiments are not limited thereto, and the chuck CK may be positioned on side portions (e.g., opposite side portions) of the substrate SUB. The magnetic plate may be positioned at a location adjacent to the chuck CK. For example, the chuck CK may be provided in a Coulomb-type bi-polar pattern electrode and/or may be a Coulomb-type bi-polar electrostatic chuck. However, embodiments are not limited thereto, and the chuck CK may be of a Johnsen Rahbek-type and/or may be a Johnsen Rahbek-type electrostatic chuck, and also provided in a monopolar pattern electrode or a unipolar pattern electrode and/or may be monopolar electrostatic chuck or a unipolar electrostatic chuck. The chuck CK will be described below.

The support unit SU and the chuck CK according to an embodiment may prevent sagging of the substrate SUB. The chuck CK may prevent the substrate SUB from sagging (or bending) by using attractive force, for example, static electricity, above the substrate SUB. The support unit SU may prevent the substrate SUB from sagging by supporting the substrate SUB under the substrate SUB. The first support unit SU1 and the second support unit SU2 may effectively prevent the substrate SUB from sagging (or bending) by supporting different portions of the substrate SUB under the substrate SUB.

By effectively preventing sagging of the substrate SUB, misalignment between the substrate SUB and the mask MK may be prevented or minimized in case that the substrate SUB is adjacent to the mask MK. In case that the alignment key of the substrate SUB is aligned with the alignment key of the mask MK in order to align the substrate SUB and the mask MK, the substrate SUB may be prevented from sagging, and stably adjacent to the mask MK, thereby effectively aligning the alignment key of the substrate SUB with the alignment key of the mask MK. Accordingly, in a deposition process, the deposition material may be deposited at a suitable location on the substrate SUB, thereby improving reliability of the deposition process.

The deposition apparatus DA according to an embodiment may not only prevent sagging of a small-sized substrate SUB and a medium-sized substrate SUB but also prevent sagging of a large-sized substrate SUB. For example, for a substrate SUB with a size of about 1,500 mm or more in width or about 2,500 mm or more in height, the first support unit SU1 may support the corner portions of the substrate SUB, and the second support unit SU2 may support the surface central portion of the substrate SUB, thereby effectively support the entire region of the large-sized substrate SUB. In case of using a large-sized substrate SUB, the substrate SUB may sag by about 6.00 mm or more so that it is important to effectively prevent the sagging of the substrate SUB. In case that the sagging of the substrate SUB increases, the substrate SUB may not be effectively attached to the mask MK.

For example, the sagging of a large-sized substrate SUB may be effectively prevented by an attractive force applied to the substrate SUB from the chuck CK together with the support unit SU.

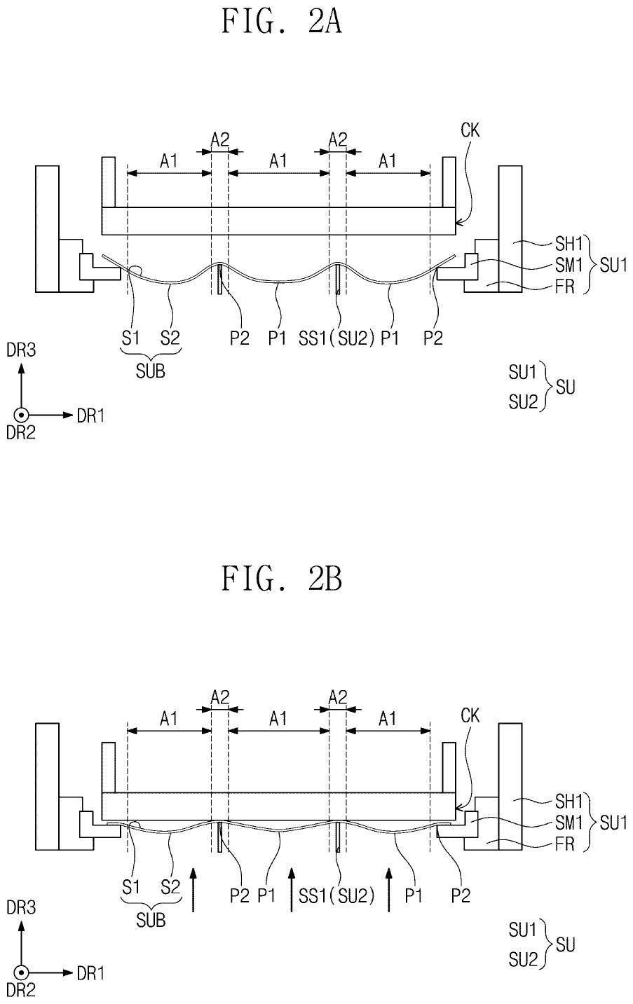

FIGS. 2A and 2B are schematic diagrams illustrating a part of a deposition apparatus according to an embodiment. FIGS. 2A and 2B illustrate a support unit SU, a chuck CK, and a substrate SUB in the deposition apparatus DA according to an embodiment.

Referring to FIG. 2A, the substrate SUB may be supported by the support unit SU, and the chuck CK may be placed above the substrate SUB. The substrate SUB may include a first part P1 and a second part P2. The second part P2 of the substrate SUB may be adjacent to the first part P1. A first distance by which the first part P1 of the substrate SUB is spaced apart from the chuck CK may be different from a second distance by which the second part P2 of the substrate SUB is spaced apart from the chuck CK. For example, the first distance may be the longest distance between the chuck CK and the first part P1 of the substrate SUB, and the second distance may be the longest distance between the chuck CK and the second part P2 of the substrate SUB. According to an embodiment, the first distance may be longer than the second distance.

In a plan view, the second support unit SU2 may be positioned between the first support units SU1.

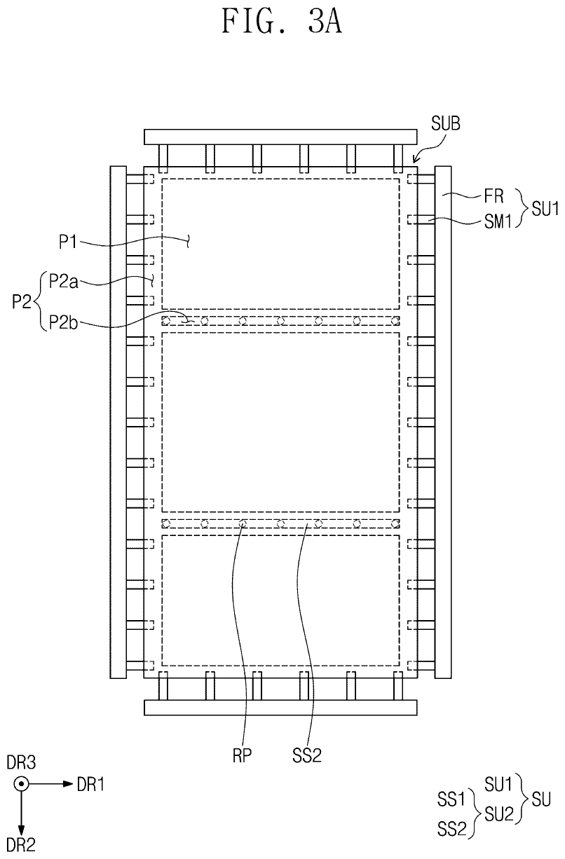

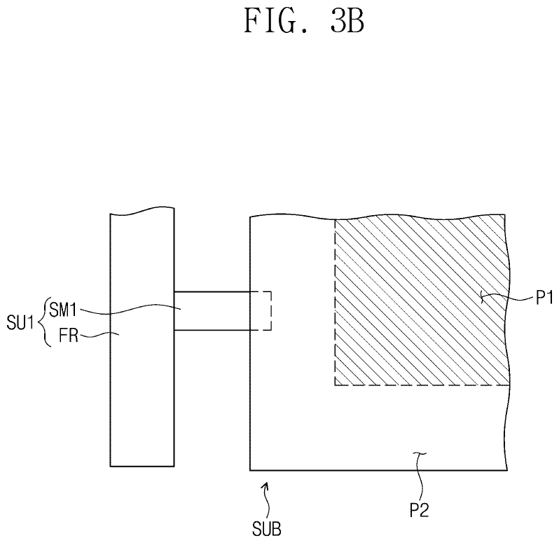

The first support unit SU1 and the second support unit SU2 may support different portions of the second part P2 of the substrate SUB. For example, the first support unit SU1 may support the corner portions of the second part P2 of the substrate SUB. The second support unit SU2 may support the central portion of the second part P2 of the substrate SUB. For example, the first support unit SU1 may be in contact with the corner portions of the second part P2 of the substrate SUB, and support a portion, of the substrate SUB, adjacent to the corner portions. The second support unit SU2 may be in contact with the central portion of the second part P2 of the substrate SUB, and support a portion of the substrate SUB adjacent to the central portion. For example, the first support unit SU1 may support a first sub-part P2a (see FIG. 3A) of the second part P2, and the second support unit SU2 may support a second sub-part P2b (see FIG. 3A) of the second part P2.

A plurality of sites (or portions) under the substrate SUB may be supported by the first support unit SU1 and the second support unit SU2, thereby effectively preventing the substrate SUB from sagging.

The chuck CK may include a first region A1 and a second region A2. The second region A2 of the chuck CK may be adjacent to the first region A1. The first region A1 of the chuck CK may overlap the first part P1 of the substrate SUB in a plan view, and the second region A2 of the chuck CK may overlap the second part P2 of the substrate SUB in a plan view. A distance between the first region A1 of the chuck CK and the first part P1 of the substrate SUB may be the first distance as the longest distance between the chuck CK and the first part P1 of the substrate SUB as described above, and a distance between the second region A2 of the chuck CK and the second part P2 of the substrate SUB may be the second distance as the longest distance between the chuck CK and the second part P2 of the substrate SUB as described above.

According to an embodiment, in case that a voltage is applied to the chuck CK, the same voltage may be applied to the first region A1 and the second region A2 of the chuck CK. However, embodiments are not limited thereto, and different voltages are respectively applied to the first region A1 and the second region A2 to make the attractive force of the chuck CK acting on respective regions of the substrate SUB differ from each other, thereby optimizing the prevention of sagging of the substrate SUB.

Referring to FIG. 2B, the substrate SUB may be supported by the first support unit SU1, and the chuck CK may be positioned on the substrate SUB. Compared to FIG. 2A, the chuck CK may be adjacent to the upper portion of the substrate SUB.

In case that the chuck CK is adjacent to the upper portion of the substrate SUB, a voltage may be applied to the chuck CK. As described above, the same voltage may be applied to, or a certain voltage for optimizing the prevention of sagging of the substrate SUB may be applied to the first region A1 and the second region A2 of the chuck CK, thereby making it possible for the chuck CK to effectively prevent sagging of the substrate SUB, together with the first support unit SU1 and the second support unit SU2. For example, the certain voltage may change according to the area of an electrode, the thickness of a dielectric layer, an applied voltage, and the permittivity of a dielectric layer. For example, the certain voltage may change according to various factors such as a design condition of a deposition apparatus DA, and the size of a substrate SUB, but is not limited to any one value.

FIG. 3A is a schematic diagram illustrating a part of a deposition apparatus according to an embodiment, and FIG. 3B is an enlarged schematic view illustrating a part of FIG. 3A. FIGS. 3A and 3B illustrate a support unit SU and a substrate SUB in a deposition apparatus DA according to an embodiment.

Referring to FIGS. 3A and 3B, the substrate SUB may include a first part P1 and a second part P2. The first part P1 and the second part P2 may be separated from each other. The second part P2 may be adjacent to the first part P1, for example, the second part P2 may surround the first part P1. The first part P1 of the substrate SUB may overlap the first region A1 of the above-described chuck CK in a plan view, and the second part P2 may overlap the second region A2 of the chuck CK in a plan view. The second part P2 may include a first sub-part P2a and a second sub-part P2b.

A first support member SM1 of a first support unit SU1 may support a portion of the second part P2 of the substrate SUB, and a second support part SS2 of a second support unit SU2 may support a portion of the second part P2 of the substrate SUB. The portion of the second part P2 supported by the first support member SM1 may be different from the portion of the second part P2 supported by the second support part SS2. For example, the first support member SM1 may support the first sub-part P2a of the second part P2 of the substrate SUB, and the second support part SS2 may support the second sub-part P2b of the second part P2 of the substrate SUB.

The second support part SS2 of the second support unit SU2 may include a protruding portion RP. The protruding portion RP may support the second part P2 of the substrate SUB. For example, in case that the protruding portion RP is omitted from the second support part SS2, the upper side of the second support part SS2 may support the second part P2, and in case that the second support part SS2 includes the protruding portion RP, the protruding portion RP may support the second part P2. The protruding portion RP may be provided in plurality, and the plurality of protruding portions RP may be spaced apart from each other.

The first support unit SU1 and the second support unit SU2 may support the entire region of the second part P2 of the substrate SUB, and may thus effectively prevent the substrate SUB from sagging. For example, the first support unit SU1 may support the corner portions of the second part P2, and the second support unit SU2 may support the central portion of the second part P2, thereby effectively preventing the substrate SUB from sagging. For example, the first sub-part P2a may be a part on the corner portions of the second part P2, and the second sub-part P2b may be a part on the central portion of the second part P2.

The first support unit SU1 and the second support unit SU2 may be in contact with the substrate SUB under the substrate SUB, and the area of a region which supports the substrate SUB may be increased, thereby making it possible to more effectively prevent sagging of not only a small to medium-sized substrate SUB but also a large-sized substrate SUB.

According to an embodiment, the number of the first support members SM1 arranged along a second direction DR2 may be greater than the number of the first support members SM1 arranged along a first direction DR1. The protruding portion RP may have a shape of a cylinder, e.g., extending in the third direction DR3.

In a deposition process to be performed later, the first support member SM1 and the second support part SS2 may each be disposed at a location that does not interfere with the deposition of a deposition material through a mask MK.

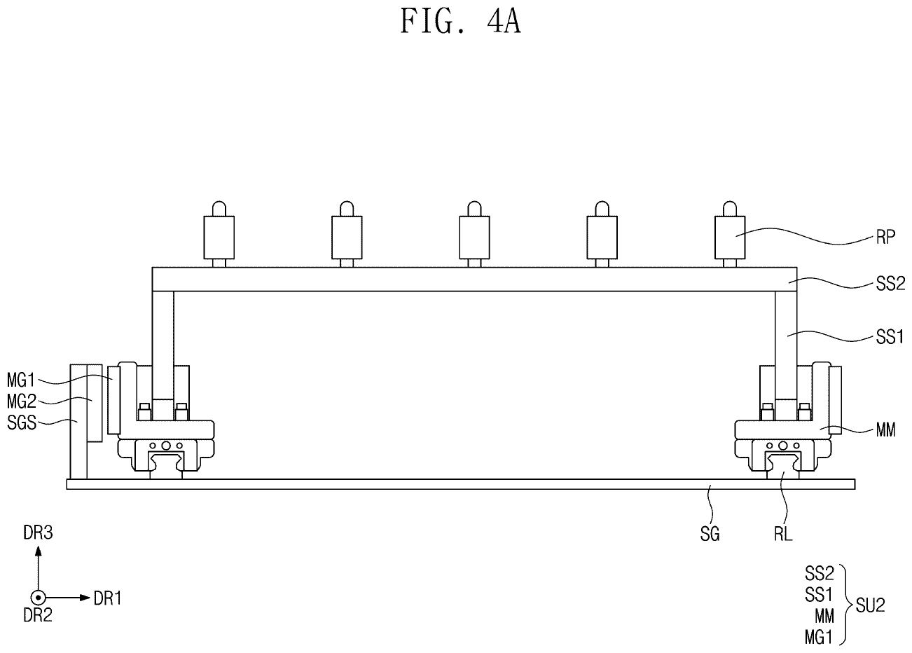

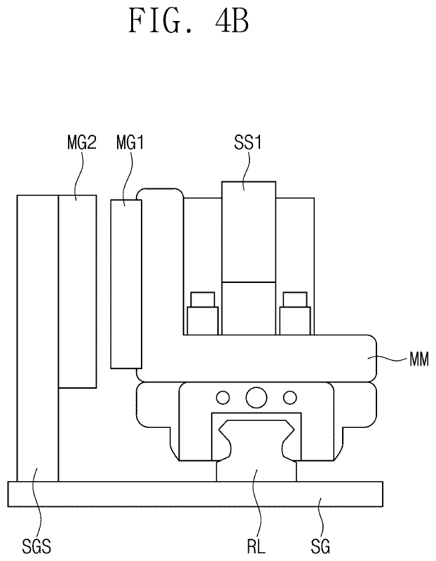

FIG. 4A is a schematic diagram illustrating a part of a deposition apparatus according to an embodiment, and FIG. 4B is an enlarged schematic view illustrating a part of FIG. 4A. FIGS. 4A and 4B illustrate a part of a second support unit SU2 of a deposition apparatus DA according to an embodiment.

Referring to FIG. 4A, the second support unit SU2 may include a first support part SS1, a second support part SS2, and a moveable member MM. A stage SG may include a rail RL and a third support part SGS. The third support part SGS may extend from a side of the stage SG in a third direction DR3.

The second support unit SU2 may include a first magnetic member MG1. As illustrated in the drawing, the first magnetic member MG1 may be coupled to the moveable member MM, but embodiments are not limited thereto, and the first magnetic member MG1 may be coupled to the first support part SS1.

The stage SG may include a second magnetic member MG2. As illustrated in the drawing, the second magnetic member MG2 may be coupled to the third support part SGS, but embodiments are not limited thereto, and the second magnetic member MG2 may be disposed on the stage SG.

At least one of the first magnetic member MG1 or the second magnetic member MG2 may be formed as an electromagnet. By providing at least one magnetic member as an electromagnet, the first magnetic member MG1 and the second magnetic member MG2 may have the same polarity, and thus the second support unit SU2 may be moveable along the rail RL in a second direction DR2. Further, the first magnetic member MG1 and the second magnetic member MG2 may have different polarities, and thus the second support unit SU2 may stop on the rail RL.

As such, using the first magnetic member MG1 and the second magnetic member MG2 may change or fix the position of the second support unit SU2 on the rail RL, and thus the second support unit SU2 may be arranged at the optimal position in which sagging of the substrate SUB is prevented.

Referring to FIG. 4B, the first magnetic member MG1 and the second magnetic member MG2 may be spaced apart from each other by a certain distance. However, embodiments are not limited thereto, and the first magnetic member MG1 and the second magnetic member MG2 may be adjacent to each other. For example, the positions and the shapes of the rail RL and the moveable member MM are not limited to what is illustrated in the drawing, and may also be partially modified to perform the same functions.

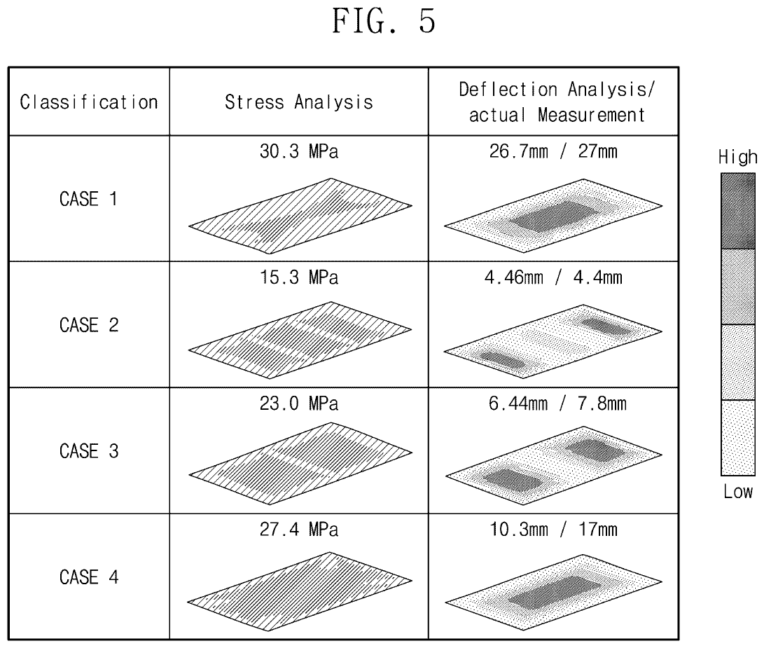

FIG. 5 is a schematic diagram illustrating experimental results of a deposition apparatus according to an embodiment and a comparison target. FIG. 5 illustrates experimental results obtained in case that the position is changed, the configuration, or the number of a support unit SU in the deposition apparatus DA.

FIG. 5 illustrates stress analyses and deflection analyses of the substrate SUB in CASE 1 through CASE 4. For example, CASE 1 is a case where the first support unit SU1 supports only the corner portions of the substrate SUB; CASE 2 is a case where the first support unit SU1 supports the corner portions of the substrate SUB, and a pair of second support units SU2 support an inner side of a surface of the substrate SUB; CASE 3 is a case where the first support unit SU1 supports the corner portions of the substrate SUB, and one of the second support units SU2 supports an inner side of a surface of the substrate SUB; and CASE 4 is a case where the corner portions of the substrate SUB are fixed by a clamp instead of the first support unit SU1. CASE 2 and CASE 3 may be examples of the deposition apparatus DA according to an embodiment.

With reference to the results of the stress analyses and the deflection analyses, it is seen that CASE 2 has the lowest stress and deflection values, and that CASE 3 has the second lowest stress and deflection values as to preventing of sagging of a large-sized substrate SUB.

Accordingly, in the deposition apparatus DA according to an embodiment, the first support unit SU1 and the second support unit SU2 may support different portions of the substrate SUB, thereby preventing a large-sized substrate SUB from sagging. For example, cracking of the substrate SUB caused by the increase in size of the substrate SUB may also be prevented.

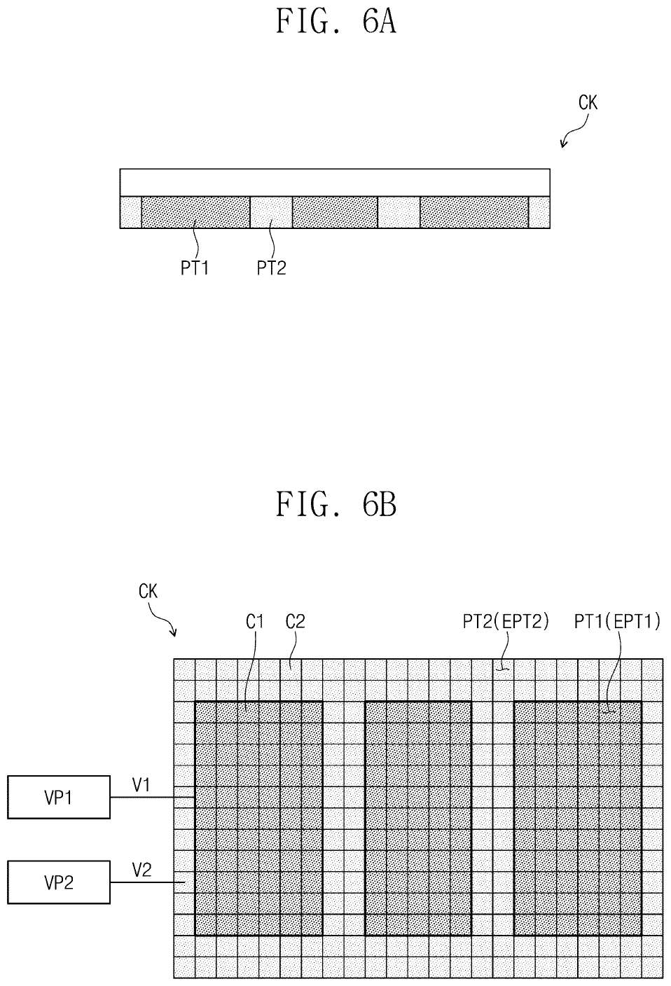

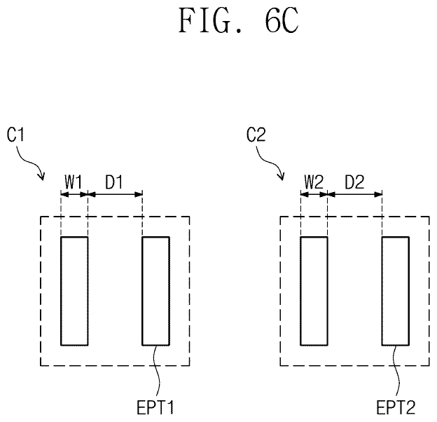

FIGS. 6A through 6C are schematic diagrams illustrating a part of a deposition apparatus according to an embodiment. FIGS. 6A and 6B illustrate a chuck CK in a deposition apparatus DA according to an embodiment. FIGS. 6C illustrate some portions of areas of each cell in a chuck CK according to an embodiment.

Referring to FIGS. 6A through 6C, the chuck CK may include a first pattern portion PT1 and a second pattern portion PT2. Different voltages may be applied to the first pattern portion PT1 and the second pattern portion PT2.

As illustrated in the drawing, the first pattern portion PT1 and the second pattern portion PT2 may be defined only in a portion of the chuck CK, but embodiments are not limited thereto, and the first pattern portion PT1 and the second pattern portion PT2 may be defined in the entire region of the chuck CK.

The first pattern portion PT1 may be adjacent to the second pattern portion PT2. The first pattern portion PT1 and the second pattern portion PT2 may be spaced apart from each other in a plan view. Each of the first pattern portion PT1 and the second pattern portion PT2 may include a plurality of pattern electrodes EPT1 or EPT2. For example, the first pattern portion PT1 may include first pattern electrodes EPT1, and the second pattern portion PT2 may include second pattern electrodes EPT2. The first pattern electrodes EPT1 and the second pattern electrodes EPT1 may have various shapes. A first voltage V1 may be applied to the first pattern portion PT1 through a first voltage member VP1, and a second voltage V2 may be applied to the second pattern portion PT2 through a second voltage member VP2. For example, the first voltage V1 applied from the first voltage member VP1 may be different from the second voltage V2 applied from the second voltage member VP2, and the voltages may vary according to a design of a deposition apparatus DA, and the size and characteristics of a substrate SUB. In case that an excessively high voltage is applied to the first pattern portion PT1 or the second pattern portion PT2, the service life (or lifespan) of the chuck CK may be reduced, and a chucking process may not be smooth.

In case that the substrate SUB has insulator characteristics, the chuck CK according to an embodiment may use a dielectric polarization mechanism. According to the specific resistivity of a dielectric layer of the chuck CK, the chuck CK may be provided in a coulomb-type bi-polar pattern electrode based on the pattern electrode, but, embodiments are not limited thereto. According to the characteristic of the substrate SUB or a design value of the chuck CK, the chuck CK may be of a Johnsen Rahbek-type, and may be provided in a monopolar pattern electrode or a unipolar pattern electrode.

The first pattern electrodes EPT1 of the first pattern portion PT1 and the second pattern electrodes EPT2 of the second pattern portion PT2 may generate different electric field values (V/m). For example, in order to consider a vertical (e.g., a direction in which the substrate SUB faces the chuck CK) force of fringe effect occurring between the pattern electrodes that are distinct from each other in each pattern electrode, the electric field value (V/m) may be calculated by being converted into force (N) using an electric field analysis (COMSOL) tool.

The first pattern electrodes EPT1 of the first pattern portion PT1 may be different in the number of pattern electrodes per unit area from the second pattern electrodes EPT2 of the second pattern portion PT2. Referring to FIG. 6B, in case that the first cell C1 of the first pattern portion PT1 and the second cell C2 of the second pattern portion PT2 have the same size, the first cell C1 may be different from the second cell C2 in the number of pattern electrodes per unit area. For example, the electrode area of the first pattern portion PT1 may be different from the electrode area of the second pattern portion PT2.

In case that the electrode area of a pattern portion is widened, the amount of residual charges on a surface increases so that a chucking process may be smoothly performed, but a de-chucking process may not be smoothly performed. Therefore, the optimal value may be selected according to the design of a deposition apparatus DA, the size and characteristics of a substrate SUB.

For example, in case that a distance D1 between the pattern electrodes in the first cell C1 is same as a distance D2 between the pattern electrodes in the second cell C2, the sum of the distances D1 between the pattern electrodes in the first cell C1 may be different from the sum of the distances D2 between the pattern electrodes in the second cell C2. Thus, the number of gaps between the pattern electrodes in the first cell C1 may be different from the number of gaps between the pattern electrodes in the second cell C2. In another example, the sum of widths W1 of the pattern electrodes in the first cell C1 may be different from the sum of widths W2 of the pattern electrodes in the second cell C2.

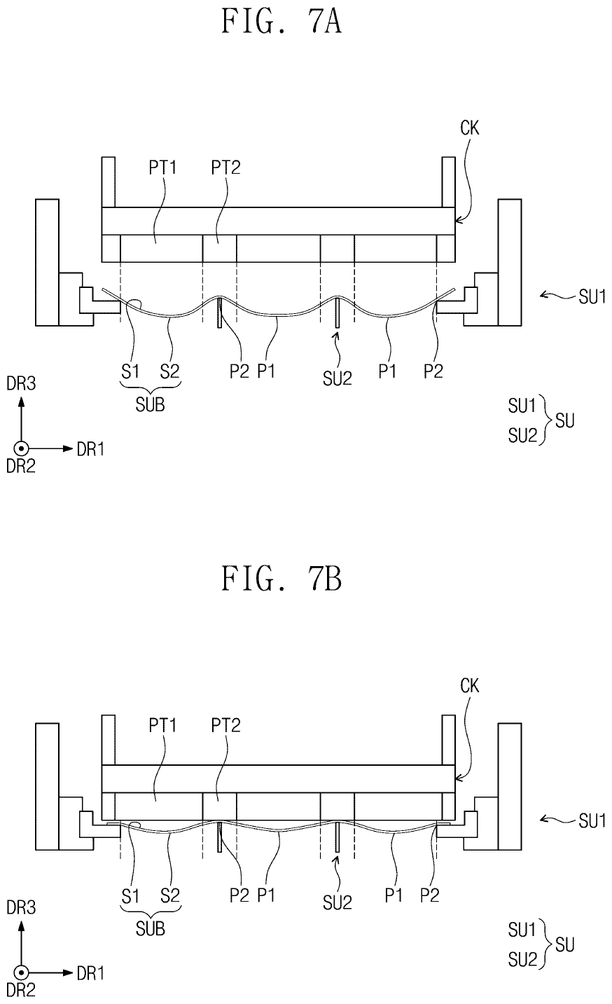

FIGS. 7A and 7B are schematic diagrams illustrating a part of a deposition apparatus according to an embodiment. FIGS. 7A and 7B illustrate a support unit SU, a chuck CK, and a substrate SUB in the deposition apparatus DA according to an embodiment.

Referring to FIGS. 7A and 7B, the chuck CK may be disposed above the substrate SUB as described in FIGS. 2A and 2B, and a first support unit SU1 and a second support unit SU2 may be disposed under the substrate SUB, thereby preventing the substrate SUB from sagging.

According to an embodiment, in case that a distance between a first pattern portion PT1 of the chuck CK and a first part P1 of the substrate SUB is a first distance, and a distance between a second pattern portion PT2 of the chuck CK and a second part P2 of the substrate SUB is a second distance, the first distance may be longer than the second distance. In case that the first distance is longer than the second distance, attractive force applied to the first part P1 of the substrate SUB through the chuck CK may be greater than attractive force applied to the second part P2 through the chuck CK. For example, in case that the first pattern portion PT1 is provided to have a larger electrode area than the second pattern portion PT2, the attractive force applied to the first part P1 may be greater than the attractive force applied to the second part P2. For example, in case that the first cell C1 of the first pattern portion PT1 is provided to be greater in the number of pattern electrodes per unit area than the second cell C2 of the second pattern portion PT2, the electrode area of the first pattern portion PT1 may be larger than the electrode area of the second pattern portion PT2. Moreover, for example, a first voltage applied to the first pattern portion PT1 may be greater than a second voltage applied to the second pattern portion PT2.

Accordingly, since the attractive force applied to the substrate SUB through the first pattern portion PT1 is greater than the attractive force applied to the substrate SUB through the second pattern portion PT2, the difference between the first distance and the second distance may be reduced. Accordingly, the sagging of the substrate SUB may be prevented across all regions of the substrate SUB.

The first pattern portion PT1 and the second pattern portion PT2 of the chuck CK may be positioned respectively at the same locations as the first region A1 (see FIG. 2A) and the second region A2 (see FIG. 2A) as described above.

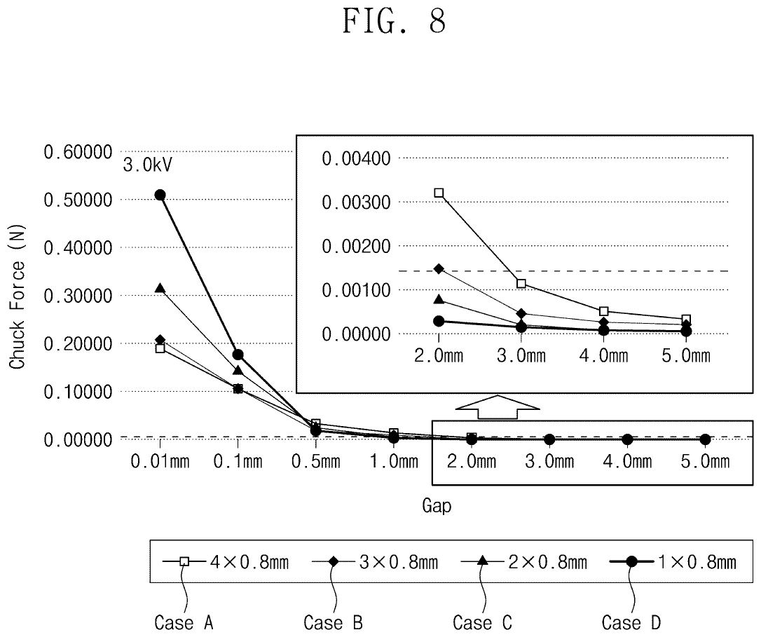

FIG. 8 shows experimental results according to various cases. FIG. 8 shows experimental results obtained while varying a first pattern portion PT1 and a second pattern portion PT2 of a chuck CK in a deposition apparatus DA according to an embodiment.

Referring to FIG. 8, the graph shows the experimental results showing the relationship between a chuck force and a gap in cases of varying the sum of gap distances between pattern electrodes in a cell while applying a voltage of 3.0 kV to a pattern portion of the chuck CK.

Case A is a case where a width of each of the pattern electrodes of the pattern portion of the chuck CK is about 4.0 mm, and a distance between adjacent pattern electrodes thereof is about 0.8 mm, Case B is a case where a width of each of the pattern electrodes of the pattern portion of the chuck CK is about 3.0 mm, and a distance between adjacent pattern electrodes thereof is about 0.8 mm, Case C is a case where a width of each of the pattern electrodes of the pattern portion of the chuck CK is about 2.0 mm, and a distance between adjacent pattern electrodes thereof is about 0.8 mm, and Case D is a case where a width of each of the pattern electrodes of the pattern portion of the chuck CK is about 1.0 mm, and a distance between adjacent pattern electrodes thereof is about 0.8 mm. The width of the pattern portion of the chuck CK herein refers to the width of each pattern electrode in the cell as described above, and the distance of the pattern portion of the chuck CK refers to the distance between the adjacent pattern electrodes in the cell.

Here, the distance between the adjacent pattern electrodes is about 0.8 mm in each case, because a chucking state of the chuck CK may not be readily released in case that the electrode area is widened and the amount of residual charges on a surface increases.

In FIG. 8, the gap refers to the distance between the substrate SUB and the chuck CK. In case that the gap is less than or equal to a certain value between about 0.5 mm to about 0.1 mm, for example, about 0.1 mm or less, the chuck force becomes higher as the sum of the widths of the pattern electrodes in the cell is higher. In case that the gap exceeds a certain value, for example, about 0.5 mm or more, as the sum of the widths of the pattern electrodes in the cell is lower, the chuck force becomes relatively higher. For example, in case that the gap is about 0.1 mm or less, the force decreases in the order of Case D, Case C, Case B, and Case A. In case that the gap is about 0.5 mm or more, the force decreases in the order of Case A, Case B, Case C, and Case D.

Adopting the case of having high force using the pattern electrodes having different electrode areas according to the gap may optimize the prevention of sagging of the substrate SUB. In case that a small-sized substrate SUB, a medium-sized substrate SUB, or a large-sized substrate SUB is used, adopting the case of having the highest force, or of having an electrode area satisfying the design condition, according to the different gaps, may optimize the prevention of sagging of the substrate SUB for each size.

According to an embodiment, for example, the first distance and the second distance may be about 2.0 mm or more, and the first distance may be longer than the second distance. Therefore, Case A may be selected for the first pattern portion PT1, and Case D may be selected for the second pattern portion PT2 in order to optimize the prevention of sagging of the substrate SUB. However, this is an example, and embodiments are not limited thereto, and various cases may be selected to optimize the prevention of sagging of the substrate SUB.

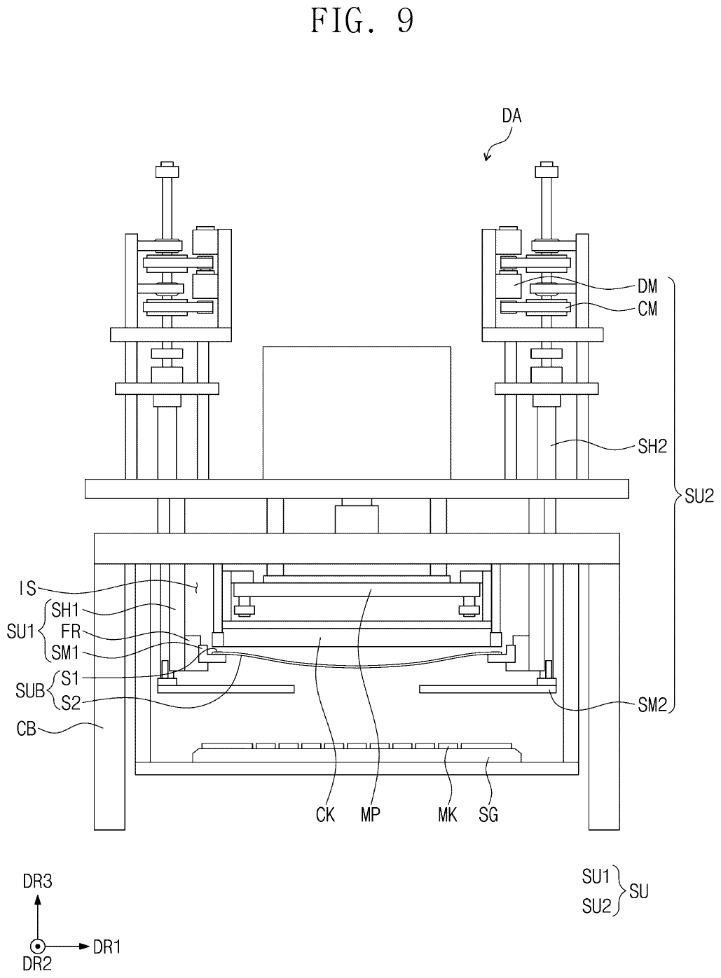

FIG. 9 is a schematic diagram illustrating a deposition apparatus DA according to an embodiment. FIG. 9 illustrates a schematic front view of the deposition apparatus DA according to an embodiment.

Hereinafter, the same reference numerals or symbols are used for the same components performing the same functions as those in FIG. 1, and descriptions thereof will be omitted for descriptive convenience.

Referring to FIG. 9, a deposition apparatus DA according to an embodiment may include a support unit SU, a chuck CK, and a deposition chamber CB.

The support unit SU may include a first support unit SU1 and a second support unit SU2.

The first support unit SU1 may include a first shaft SH1, a frame FR, and a first support member SM1, as described with reference to FIG. 1.

The second support unit SU2 may include a second shaft SH2, a second support member SM2, a driving member DM, and a coupling member CM.

The second shaft SH2 may extend to an inner space IS in the deposition chamber CB. The second support member SM2 may bend and extend from the second shaft SH2. The second support member SM2 may rotate about the second shaft SH2 to move. For example, the second support member SM2 may rotate about a direction parallel to a third direction DR3 to move. The driving member DM may move the second support member SM2 by rotating or lifting/lowering the second support member SM2. The coupling member CM may couple the driving member DM to the second shaft SH2. As illustrated in the drawing, the driving member DM and the coupling member CM may be disposed outside the deposition chamber CB. However, embodiments are not limited thereto, and the driving member DM and the coupling member CM may also be disposed inside the deposition chamber CB.

The first shaft SH1 may move up and down in the inner space IS. Accordingly, the frame FR and the first support member SM1 may move up and down in the inner space IS, and support the substrate SUB at various positions.

The second shaft SH2 may move up and down in the inner space IS. Accordingly, the second support member SM2 may move up and down in the inner space IS, and may rotate and move, thereby supporting the substrate SUB at various positions.

According to the positions of the first support member SM1 and the second support member SM2, the first support member SM1 and the second support member SM2 may support the substrate SUB simultaneously, or either of the first support member SM1 or the second support member SM2 may support the substrate SUB.

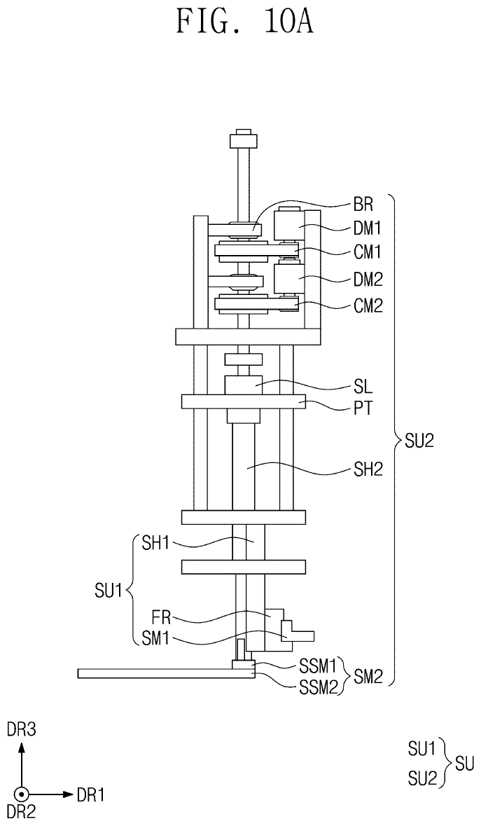

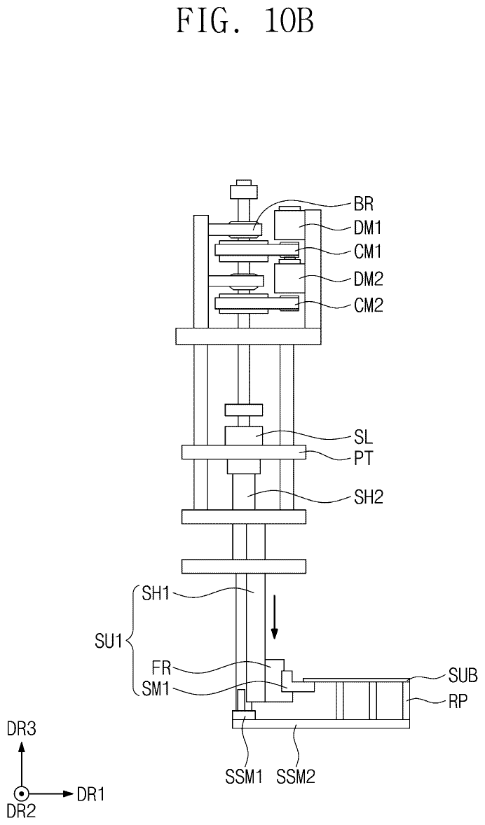

FIGS. 10A and 10B are schematic diagrams illustrating a part of a deposition apparatus according to an embodiment. FIGS. 10A and 10B illustrate a support unit SU of the deposition apparatus DA according to an embodiment.

Referring to FIGS. 10A and 10B, a second support unit SU2 according to an embodiment may include a second shaft SH2, a second support member SM2, driving members DM1 and DM2, and coupling members CM1 and CM2. For example, the second support unit SU2 may include a sealing member SL, a bearing BR, and a support plate PT. The sealing member SL, the bearing BR, and the support plate PT may support the second shaft SH2 not to deviate from a certain range in case that the second shaft SH2 moves up and down or rotates to move, and may allow the second shaft SH2 to move up and down smoothly or rotate to move smoothly.

The driving member DM may include a first driving member DM1 and a second driving member DM2. The first driving member DM1 may be disposed above the second driving member DM2. The coupling member CM may include a first coupling member CM1 and a second coupling member CM2. The first coupling member CM1 may be disposed above the second coupling member CM2. The first coupling member CM1 may couple the first driving member DM1 to the second shaft SH2, and the second coupling member CM2 may couple the second driving member DM2 to the second shaft SH2. The first driving member DM1 may be a ball screw-type, and the second driving member DM2 may be a spline motor-type. However, embodiments are not limited thereto, and the first driving member DM1 may be a spline motor-type, or the second driving member DM2 may be a ball screw-type, and the first driving member DM1 and the second driving member DM2 may be of the same type.

Since a ball screw-type or spline motor-type is used instead of a cylinder-type, the second shaft SH2 may perform up-and-down movement, and rotational movement at the same time. Accordingly, the second support member SM2 about the second shaft SH2 may be rotated, and the second support member SM2 may be lifted or lowered. For example, using a motor-type instead of a cylinder-type may make it possible to secure the precision, speed, and degree of freedom of rotation in controlling the second support member SM2 through the second shaft SH2.

The second support member SM2 may include a plurality of sub-members SSM1 and SSM2. The second support member SM2 may include a first sub-member SSM1 and a second sub-member SSM2. It is illustrated that the first sub-member SSM1 is disposed above the second sub-member SSM2 in the drawing. However, embodiments are not limited thereto, and the second sub-member SSM2 may be disposed above the first sub-member SSM1. The first sub-member SSM1 may extend in a direction (e.g., the second direction DR2), and the second sub-member SSM2 may extend in another direction (e.g., the first direction DR1). For example, the angle between the first sub-member SSM1 and the second sub-member SSM2 may be about 90°.

Referring to FIG. 10B, the first shaft SH1 may move up and down in the inner space IS. Accordingly, the frame FR and the first support member SM1 may move up and down in the inner space IS, and support the substrate SUB at various positions.

The second shaft SH2 may move up and down in the inner space IS. Accordingly, the second support member SM2 may move up and down in the inner space IS, and rotate to move, thereby supporting the substrate SUB at various positions.

The directions in which the first sub-member SSM1 and the second sub-member SSM2 of the second support member SM2 are oriented may change according to the lifting/lowering and the rotation of the second shaft SH2. Referring to FIG. 10A, the first sub-member SSM1 may be disposed toward the second direction DR2, and the second sub-member SSM2 may be disposed toward the opposite direction of the first direction DR1. Referring to FIG. 10B, compared to the case of FIG. 10A, the second shaft SH2 may move up and down and rotate about 180° about the third direction DR3, and the first sub-member SSM1 may be disposed toward the opposite direction of the second direction DR2, and the second sub-member SSM2 may be disposed toward the first direction DR1.

As illustrated in the drawing, the substrate SUB may be supported by the first support member SM1 and the second support member SM2 simultaneously. However, embodiments are not limited to what is illustrated in the drawing, and either of the first support member SM1 or the second support member SM2 may support the substrate SUB.

The second sub-member SSM2 may include a protruding portion RP. The protruding portion RP may support the substrate SUB. For example, in case that the protruding portion RP is omitted from the second sub-member SSM2, the upper side of the second sub-member SSM2 may support the substrate SUB; and in case that the protruding portion RP is included in the second sub-member SSM2, the protruding portion RP may support the substrate SUB. The protruding portion RP may be provided in plurality, and the plurality of protruding portions RP may be spaced apart from each other.

Referring to FIG. 3A together, the second sub-member SSM2 of the second support member SM2 may support the second part P2 of the substrate SUB as described above. As described above, the first support member SM1 of the first support unit SU1 may support a portion of the second part P2 (see FIG. 3A) of the substrate SUB, and the second support member SM2 of the second support unit SU2 may support a portion of the second part P2 (see FIG. 3A) of the substrate SUB. For example, the first support member SM1 may support the first sub-part P2a (see FIG. 3A) of the second part P2 (see FIG. 3A), and the second sub-member SSM2 may support the second sub-part P2b (see FIG. 3A) of the second part P2 (see FIG. 3A).

As the second support member SM2 may rotate about the second shaft SH2, the second sub-member SSM2 of the second support member SM2 may be adjusted, as needed, to support or not to support the second sub-part P2b (see FIG. 3A) of the second part P2 (see FIG. 3A).

As described above in the embodiment, sagging of the substrate SUB may be effectively prevented through the first support member SM1 and the second support member SM2.

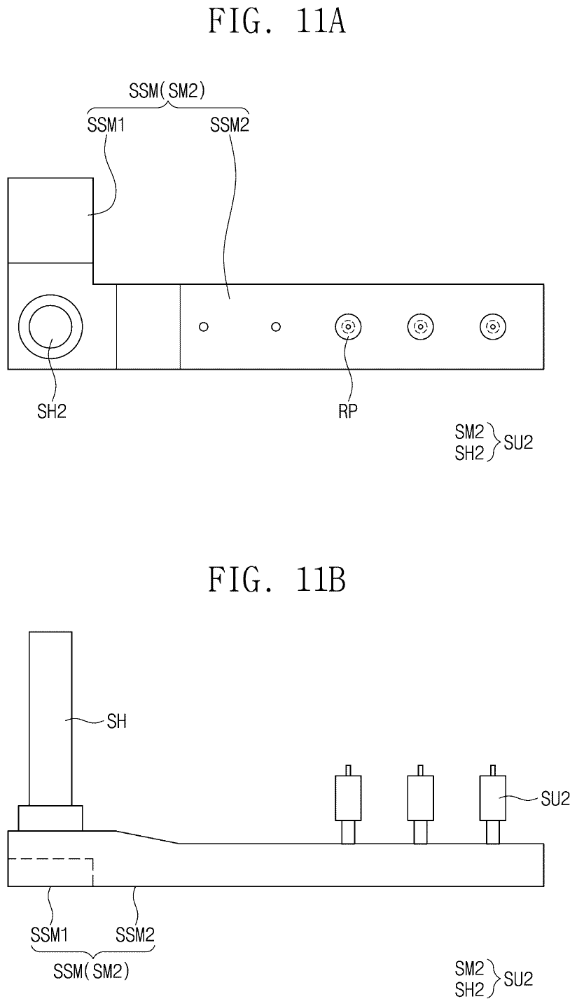

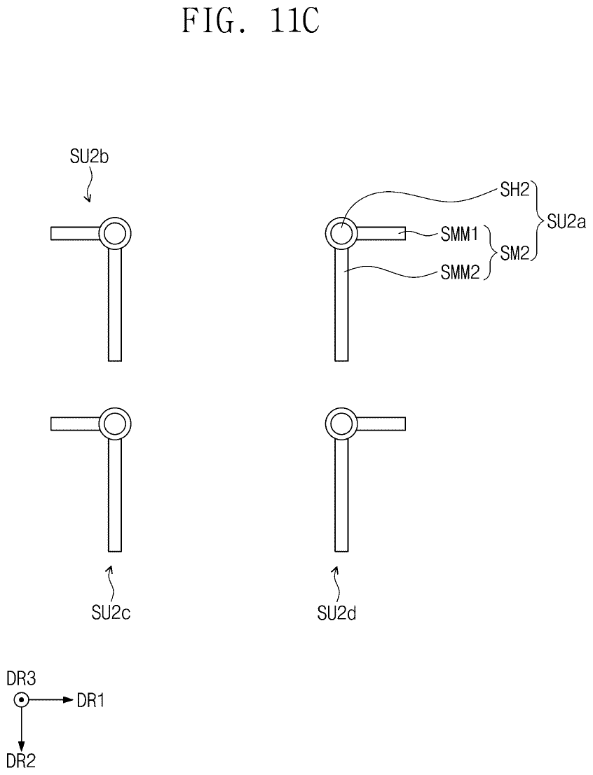

FIGS. 11A through 11C are schematic diagrams illustrating a part of a deposition apparatus according to an embodiment. FIGS. 11A through 11C illustrate a part of a support unit SU of the deposition apparatus DA according to an embodiment.

Referring to FIGS. 11A and 11B, a second support member SM2 may include a plurality of sub-members SSM. The second support member SM2 may include a first sub-member SSM1 and a second sub-member SSM2. The first sub-member SSM1 may extend in a direction, and the second sub-member SSM2 may extend in another direction differing from the direction. For example, the angle between the extending direction of the first sub-member SSM1 and the extending direction of the second sub-member SSM2 may be about 90°. The second sub-member SSM2 may include a protruding portion RP.

Referring to FIG. 11C, a plurality of second support units SU2a, SU2b, SU2c, and SU2d may be provided. The plurality of second support units SU2a, SU2b, SU2c, and SU2d may be spaced apart from each other. As illustrated in the drawing, the plurality of second support units SU2a, SU2b, SU2c, and SU2d may be spaced apart from each other along a second direction DR2, and also spaced apart from each other along a first direction DR1. However, embodiments are not limited to what is illustrated in the drawing, and the second support unit SU2a, SU2b, SU2c, or SU2d may be spaced apart from any one second support unit SU2a, SU2b, SU2c, or SU2d along a certain direction between the first direction DR1 and the second direction DR2.

Hereinafter, a deposition method by using a deposition apparatus DA will be described. The below-described deposition method according to an embodiment may be a deposition method by using the above-described deposition apparatus DA. However, embodiments are not limitedly applied to the deposition apparatus DA as described above, and may also be applied to another deposition apparatus DA that performs substantially the same functions.

For the convenience of description, the below-described deposition apparatus DA will be described together with reference to the previous drawings.

According to an embodiment, the deposition method may include disposing a chuck CK on a substrate SUB, applying power to the chuck CK, disposing the substrate SUB on a mask MK, forming a deposition pattern on the substrate SUB, and removing the substrate SUB and the chuck CK.

The deposition method according to embodiments are not limited to the above-mentioned operations, processes, or steps, the order of the operations, processes, or steps to be performed may be partially changed, and operations, processes, or steps of changing positions of some components in the deposition apparatus DA may also be performed between the operations, processes, or steps.

The operation of disposing the chuck CK on the substrate SUB according to an embodiment may include loading the substrate SUB into a deposition chamber CB. For example, loading devices such as a robot arm may be used to load the substrate SUB into an inner space IS of the deposition chamber CB. For example, to avoid interferences between the components, the operation of changing a position of each component may also be performed.

The operation of disposing the chuck CK on the substrate SUB may include supporting the substrate SUB using a support unit SU, e.g., supporting the substrate SUB using the first support unit SU1 and the second support unit SU2 as described above. This makes it possible to prevent sagging of the substrate SUB.

In the operation of applying power to the chuck CK according to an embodiment, power may be applied to the chuck CK to generate attractive force between the chuck CK and the substrate SUB, thereby preventing the substrate SUB from sagging (or bending).

In the operation of disposing the substrate SUB on the mask MK according to an embodiment, the substrate SUB, which is prevented from sagging by using the support unit SU and the chuck CK, may be disposed on the mask MK. For example, the support unit SU and the chuck CK may move along a third direction DR3 together with the substrate SUB. For example, the first support unit SU1 may move together with the substrate SUB in the third direction DR3, and the second support unit SU2 may also move together with the substrate SUB in the third direction DR3, or move to a position where the substrate SUB is moveable.

In the operation of disposing the substrate SUB on the mask MK, the alignment key of the substrate SUB may be aligned with the alignment key of the mask MK, thereby preventing a deposition material from being deposited in an unwanted region of the substrate SUB.

In the operation of forming a deposition pattern on the substrate SUB according to an embodiment, the alignment key of the substrate SUB and the alignment key of the mask MK may be aligned to arrange the substrate SUB and the mask MK, and then the deposition material may be sprayed to form the deposition pattern on the substrate SUB.

In the operation of removing the substrate SUB and the chuck CK according to an embodiment, the above-described operations may be performed in reverse order. For example, an operation of cancelling the power applied to the chuck CK, an operation of separating the chuck CK from the substrate SUB, and an operation of separating the substrate SUB from the mask MK may be included. In each of the operations, the chuck CK and the substrate SUB may be moveable along the third direction DR3, and the support unit SU that supports the substrate SUB may also be moveable along the third direction DR3.

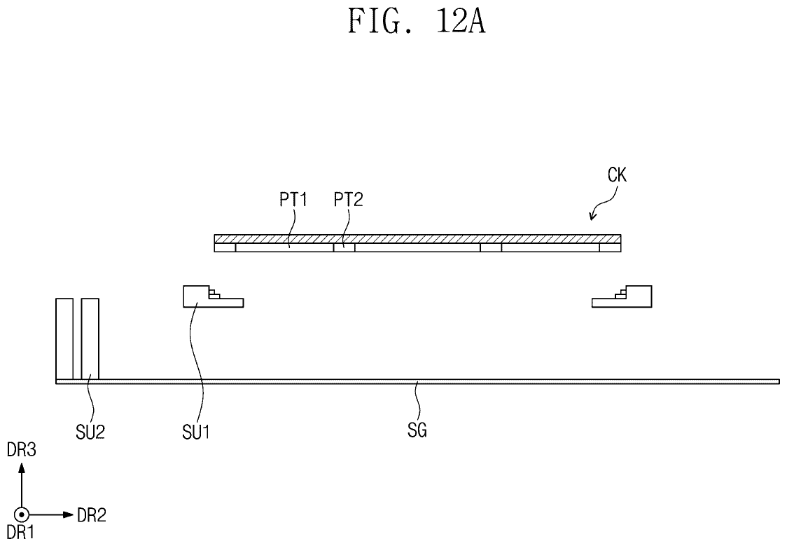

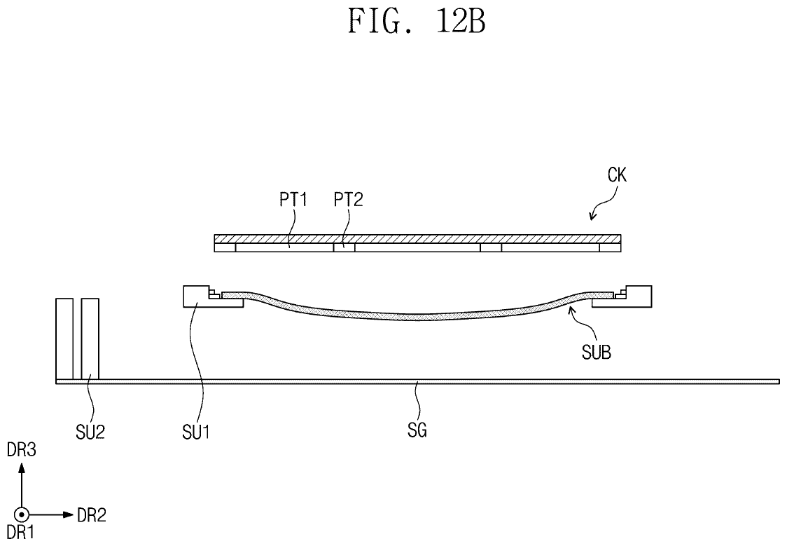

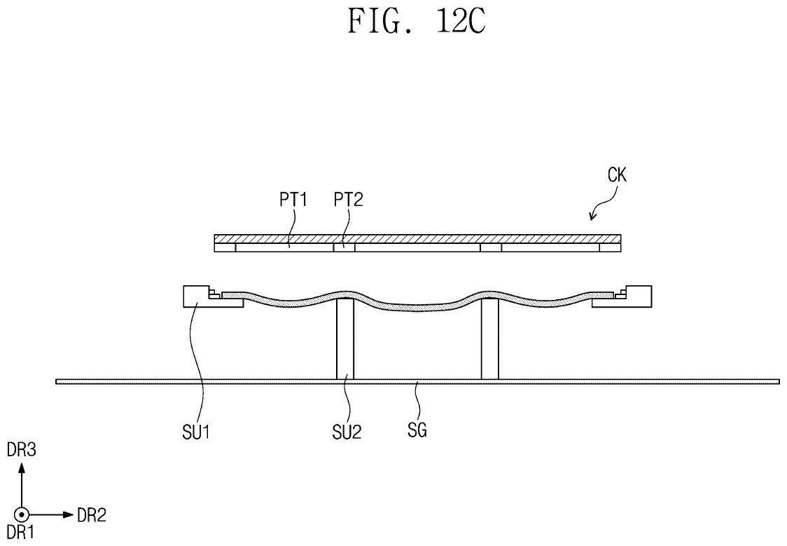

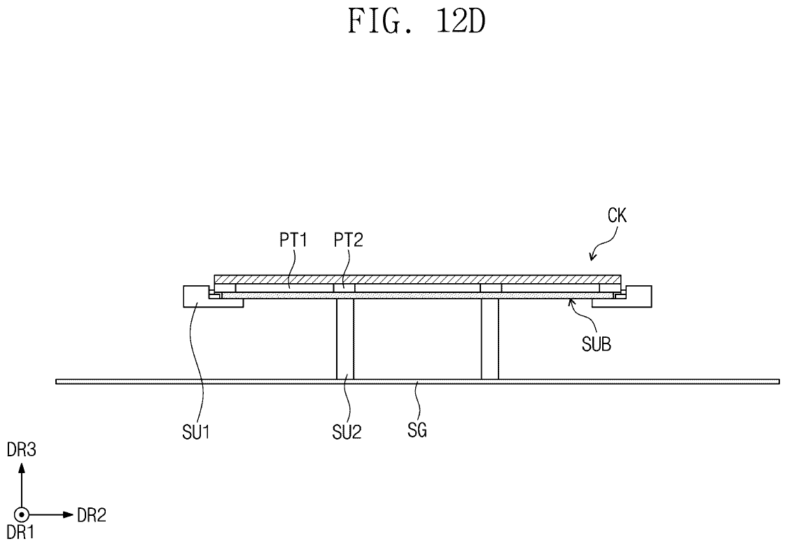

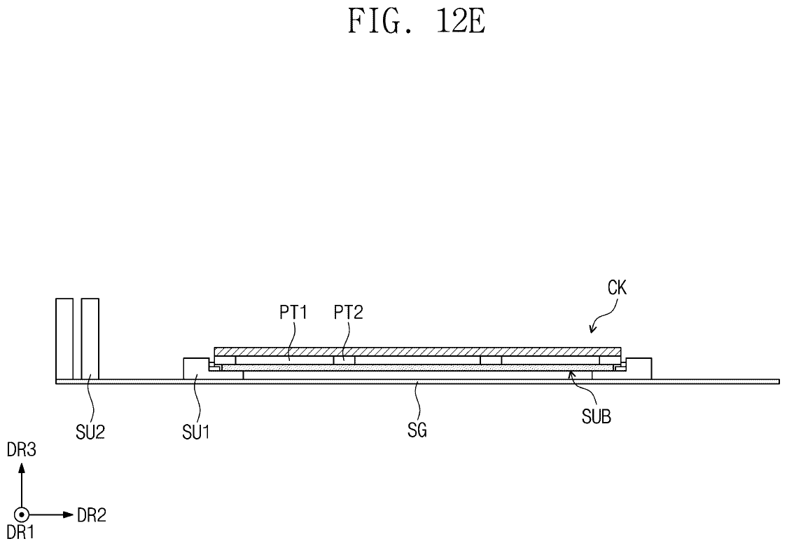

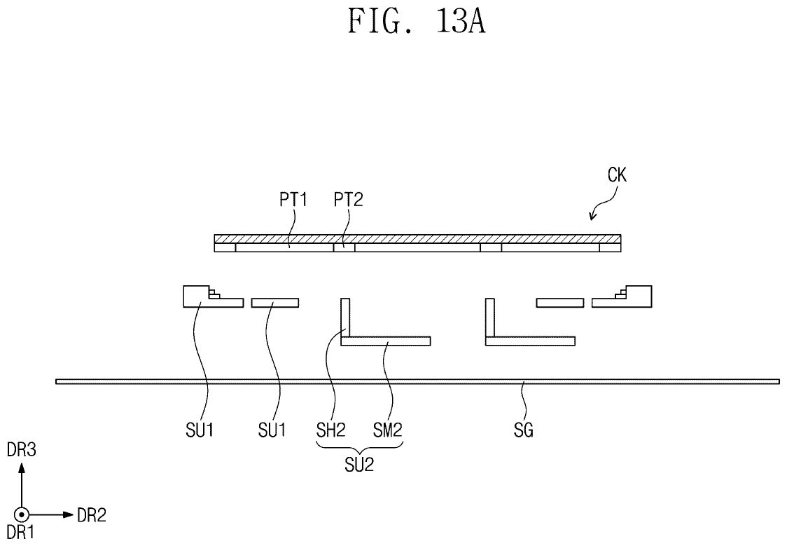

FIGS. 12A through 12D are schematic diagrams illustrating some operations of a deposition method by using a deposition apparatus according to an embodiment. FIGS. 12A through 12D illustrate a deposition method by using the deposition apparatus DA according to the embodiment described in FIG. 1.

Referring to FIG. 12A, the chuck CK, the first support unit SU1, and the second support unit SU2 may be prepared before the substrate SUB is loaded.

Referring to FIG. 12B, the substrate SUB may be loaded, and then the substrate SUB may be supported by the first support unit SU1.

Referring to FIG. 12C, the second support unit SU2 may be moved along the stage SG to support the substrate SUB.

Referring to FIG. 12D, the chuck CK may be disposed above the substrate SUB. For example, applying a voltage to the chuck CK may generate attractive force between the chuck CK and the substrate SUB. Each of the first support unit SU1 and the second support unit SU2 may support a region of the chuck CK overlapping the second pattern portion PT2 in a plan view. The chuck CK and the substrate SUB may be aligned with each other.

Referring to FIG. 12E, the chuck CK may be aligned with the substrate SUB, and then the second support unit SU2 may be moveable along the stage SG. The chuck CK and the substrate SUB aligned with each other may be moveable adjacent to the stage SG. For example, deposition may then be performed on the substrate using a mask and deposition sources.

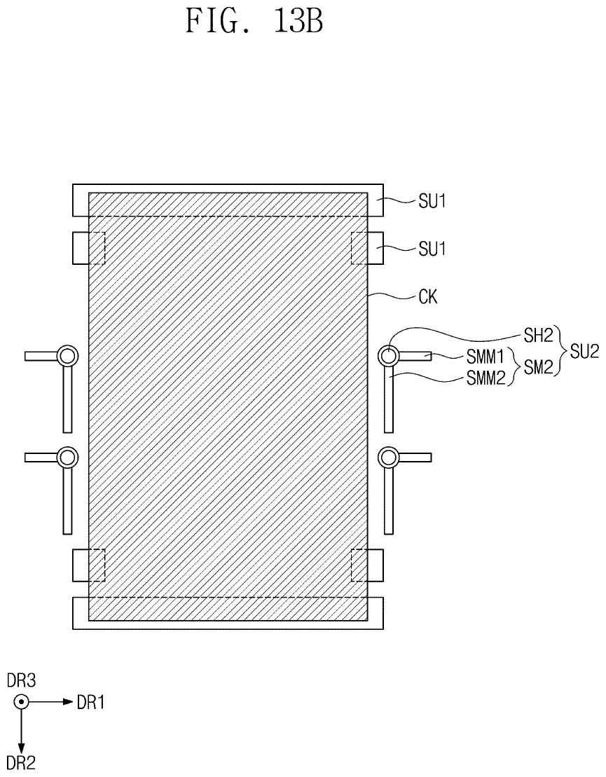

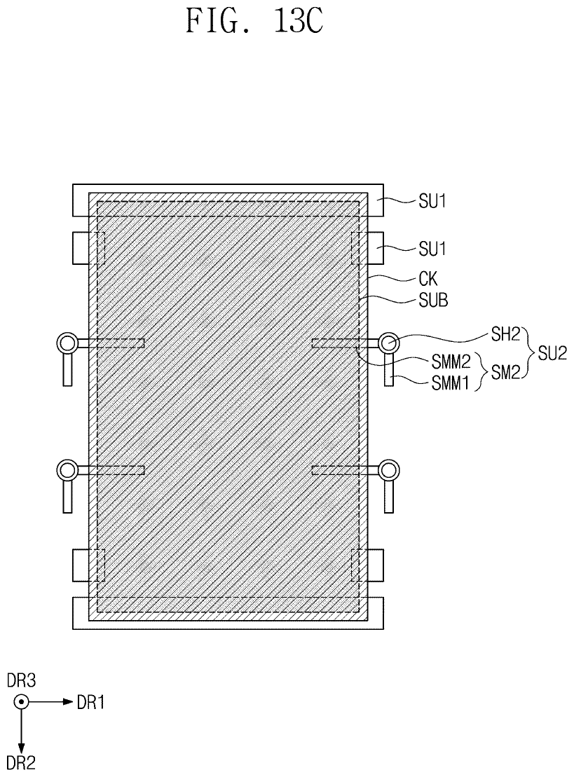

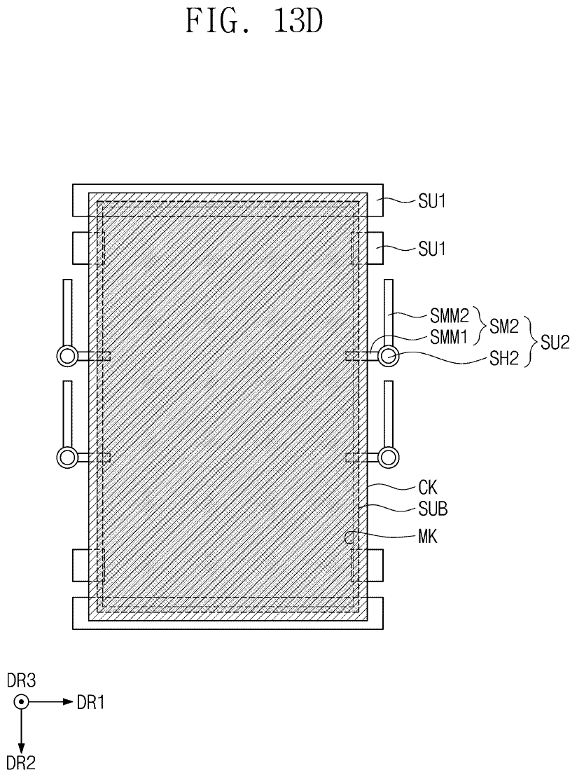

FIGS. 13A through 13D are schematic diagrams illustrating some operations of a deposition method by using a deposition apparatus according to an embodiment. FIGS. 13A through 13D illustrate a deposition method by using the deposition apparatus DA according to the embodiment described in FIG. 9.

FIG. 13A is a schematic front view of the deposition apparatus DA before the substrate SUB is loaded. Referring to FIG. 13A, the chuck CK, the first support unit SU1, and the second support unit SU2 may be prepared before the substrate SUB is loaded. For example, the second support unit SU2 may adjust the position of the second support member SM2 as long as the second support unit SU2 does not block the loading of the substrate SUB.

FIG. 13B is a schematic plan view of the deposition apparatus DA of FIG. 13A. The first support unit SU1 and the second support unit SU2 may be positioned under the chuck CK.

FIG. 13C is a schematic plan view of the deposition apparatus DA (see FIG. 9) illustrating a state in which the substrate SUB is loaded. The first support unit SU1 may support the substrate SUB. The second support member SM2 of the second support unit SU2 may rotate about the second shaft SH2. For example, the second support member SM2 may support the substrate SUB. For example, a voltage may be applied to the chuck CK to generate attractive force between the chuck CK and the substrate SUB. For example, the positions of the first support unit SU1 and the second support unit SU2 may be moved along the third direction DR3.

FIG. 13D is a schematic plan view of the deposition apparatus DA (see FIG. 9) illustrating a state in which the substrate SUB is disposed on the mask MK. The first support unit SU1 may support the substrate SUB. The second support member SM2 of the second support unit SU2 may rotate about the second shaft SH2. For example, the second support member SM2 may support the mask MK. For example, the positions of the first support unit SU1 and the second support unit SU2 may be moved along the third direction DR3.

A deposition apparatus according to an embodiment may improve process reliability and reduce the process costs and time by preventing sagging of a substrate to avoid the occurrence of defects such as shadows in a deposition process.

A deposition apparatus according to an embodiment may prevent sagging of a substrate using a chuck and a support unit.

A deposition apparatus according to an embodiment may effectively prevent sagging of a large-sized substrate by determining the positions of support units by reflecting a degree of deflection of the substrate caused by the increase in size of the substrate.

A deposition apparatus according to an embodiment may effectively prevent sagging of a substrate by reflecting a degree of deflection in each portion of the substrate, and varying a pattern portion for each portion of a chuck.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition apparatus comprising:
a support unit that supports a second surface of a substrate, the substrate including a first surface and the second surface opposed to the first surface; and
a chuck facing the first surface of the substrate, and including a first pattern portion and a second pattern portion that are adjacent to each other and receive different voltages, respectively, wherein
the substrate includes a first part overlapping the first pattern portion of the chuck and a second part overlapping the second pattern portion of the chuck, and
the support unit includes a first support unit and a second support unit that support different portions of the second part of the substrate.

2. The deposition apparatus of claim 1, wherein
each of the first pattern portion and the second pattern portion of the chuck includes a plurality of pattern electrodes, and
the first pattern portion and the second pattern portion have different numbers of the pattern electrodes per unit area from each other.

3. The deposition apparatus of claim 1, further comprising:
a deposition chamber including an inner space, the inner space accommodating the support unit, the substrate, and the chuck; and
a stage accommodated in the inner space of the deposition chamber, and spaced apart from the chuck with the substrate disposed between the stage and the chuck, wherein
the first support unit includes:
a first shaft extending from the deposition chamber to the inner space of the deposition chamber,
a frame connected to the first shaft, and surrounding the substrate, and
a first support member extending from the frame toward the substrate, and
the second support unit includes:
a pair of first support parts extending from the stage to the substrate, and
a second support part extending in a direction intersecting an extending direction of the pair of first support parts to connect the pair of first support parts to each other.

4. The deposition apparatus of claim 3, wherein
the stage comprises a rail extending in a direction,
the second support unit further comprises a moveable member, and
the moveable member has a side coupled to the pair of first support parts and another side coupled to the rail, and is moveable in the direction.

5. The deposition apparatus of claim 3, wherein the second support part comprises a protruding portion protruding toward the second surface of the substrate.

6. The deposition apparatus of claim 3, wherein the second support unit is provided in plurality.

7. The deposition apparatus of claim 1, further comprising:
a deposition chamber including an inner space accommodating the support unit, the substrate, and the chuck, wherein
the first support unit includes:
a first shaft extending from the deposition chamber to the inner space of the deposition chamber,
a frame connected to the first shaft, and surrounding the substrate, and
a first support member extending from the frame toward the substrate, and
the second support unit includes:
a second shaft extending to the inner space of the deposition chamber, and
a second support member that bends and extends from the second shaft, and rotates about the second shaft to move.

8. The deposition apparatus of claim 7, wherein the second support unit further comprises:
a driving member that moves the second support member by rotating or lifting/lowering the second support member; and
a coupling member that couples the driving member to the second shaft.

9. The deposition apparatus of claim 7, wherein the second support member comprises a plurality of sub-members extending in different directions, respectively.

10. The deposition apparatus of claim 9, wherein each of the plurality of sub-members comprises a protruding portion protruding toward the second surface of the substrate.

11. A deposition apparatus comprising:
a support unit that supports a second surface of a substrate, the substrate including a first surface and the second surface opposed to the first surface; and
a chuck facing the first surface, and including a first pattern portion and a second pattern portion that are adjacent to each other and receive different voltages, wherein
the substrate includes:
a first part overlapping the first pattern portion of the chuck, and spaced apart from the chuck by a first distance, and
a second part overlapping the second pattern portion of the chuck, and spaced apart from the chuck by a second distance different from the first distance, and
the support unit includes:
a first support unit and a second support unit that support different portions of the second part.

12. The deposition apparatus of claim 11, wherein
each of the first pattern portion and the second pattern portion includes a plurality of pattern electrodes, and
the first pattern portion and the second pattern portion have different numbers of the pattern electrodes per unit area from each other.

13. The deposition apparatus of claim 11, further comprising:
a deposition chamber including an inner space accommodating the support unit, the substrate, and the chuck; and
a stage accommodated in the inner space of the deposition chamber, and spaced apart from the chuck with the substrate disposed between the stage and the chuck, wherein
the first support unit includes:
a first shaft extending from the deposition chamber to the inner space of the deposition chamber,
a frame connected to the first shaft, and surrounding the substrate, and
a first support member extending from the frame toward the substrate,
the stage includes:
a rail extending in a direction, and
the second support unit further includes:
a pair of first support parts extending from the stage to the substrate,
a second support part extending in a direction intersecting an extending direction of the pair of first support parts to connect the pair of first support parts to each other, and
a moveable member that has a side coupled to the pair of first support parts and another side coupled to the rail, and is moveable in the direction.

14. The deposition apparatus of claim 11, further comprising:
a deposition chamber including an inner space, the inner space accommodating the support unit, the substrate, and the chuck, wherein
the first support unit includes:
a first shaft extending from the deposition chamber to the inner space of the deposition chamber,
a frame connected to the first shaft, and surrounding the substrate, and
a first support member extending from the frame toward the substrate, and
the second support unit includes:
a second shaft extending to the inner space of the deposition chamber,
a second support member that bends and extends from the second shaft, and rotates about the second shaft to move, and
a driving member coupled to the second shaft, the driving member that moves the second support member by rotating or lifting/lowering the second support member.

15. A deposition apparatus comprising:
a support unit that supports a second surface of a substrate, the substrate including a first surface and the second surface opposed to the first surface; and
a chuck facing the first surface of the substrate, the chuck that fixes the substrate to the support unit, wherein
the substrate includes:
a first part spaced apart from the chuck by a first distance, and
a second part adjacent to the first part, and spaced apart from the chuck by a second distance different from the first distance, and
the support unit includes:
a first support unit and a second support unit that support different portions of the second part.

16. The deposition apparatus of claim 15, wherein
the chuck comprises:
a first pattern portion overlapping the first part of the substrate; and
a second pattern portion overlapping the second part of the substrate,
the first pattern portion and the second pattern portion of the chuck are configured to receive different voltages, respectively.

17. The deposition apparatus of claim 16, wherein
each of the first pattern portion and the second pattern portion of the chuck comprises a plurality of pattern electrodes, and
the first pattern portion and the second pattern portion of the chuck have different electrode areas of the pattern electrodes from each other.

18. The deposition apparatus of claim 17, wherein
each of the first pattern portion and the second pattern portion of the chuck comprises a plurality of pattern electrodes, and
the first pattern portion and the second pattern portion of the chuck have different numbers of the pattern electrodes per unit area from each other.

19. The deposition apparatus of claim 15, further comprising:
a deposition chamber including an inner space, the inner space accommodating the support unit, the substrate, and the chuck; and
a stage accommodated in the inner space of the deposition chamber, and spaced apart from the chuck with the substrate disposed between the stage and the chuck, wherein
the first support unit includes:
a first shaft extending from the deposition chamber to the inner space of the deposition chamber,
a frame connected to the first shaft, and surrounding the substrate, and
a first support member extending from the frame toward the substrate,
the stage includes:
a rail extending in a direction, and
the second support unit further includes:
a pair of first support parts extending from the stage to the substrate,
a second support part extending in a direction intersecting an extending direction of the pair of first support parts to connect the pair of first support parts to each other, and
a moveable member includes a side coupled to the pair of first support parts and another side coupled to the rail, and is moveable in the direction.

20. The deposition apparatus of claim 15, further comprising:
a deposition chamber including an inner space, the inner space accommodating the support unit, the substrate, and the chuck, wherein
the first support unit includes:
a first shaft extending from the deposition chamber to the inner space of the deposition chamber;
a frame connected to the first shaft, and surrounding the substrate; and
a first support member extending from the frame to the substrate, and
the second support unit includes:
a second shaft extending to the inner space of the deposition chamber;
a second support member that bends and extends from the second shaft, and rotates about the second shaft to move; and
a driving member coupled to the second shaft, the driving member that moves the second support member by rotating or lifting/lowering the second support member.
